(19) United States
(12) Patent Application Publication
(10) Pub. No.: US 2016/0218189 A1
(43) Pub. Date: Jul. 28, 2016

(54) SEMICONDUCTOR DEVICE

(71) Applicant: Kabushiki Kaisha Toshiba, Tokyo (JP)

(72) Inventor: Kohei Oasa, Nonoichi Ishikawa (JP)

(21) Appl. No.: 14/836,579

(22) Filed: Aug. 26, 2015

(30) Foreign Application Priority Data
Jan. 28, 2015 (JP) 2015-014156

(51) Int. Cl. H01L 29/40; H01L 29/20; H01L 29/80

(52) U.S. Cl. CPC H01L 29/404; H01L 29/802; H01L 29/2003

(57) ABSTRACT

According to one embodiment, a semiconductor device includes: a field effect transistor provided in a semiconductor layer and including a gate electrode, a source electrode, and a drain electrode; a first insulating layer provided on the field effect transistor; a first field plate electrode provided on the first insulating layer to overlap the gate electrode, and coupled to one of the gate electrode and the source electrode; a second insulating layer provided on the first field plate electrode; and a second field plate electrode provided on the second insulating layer and above the first field plate electrode, and coupled to the other one of the gate electrode and the source electrode. The second field plate electrode includes a first electrode portion and a second electrode portion spaced apart by a first space.

### CROSS-REFERENCE TO RELATED APPLICATIONS

This application is based upon and claims the benefit of priority from Japanese Patent Application No. 2015-014156, filed Jan. 28, 2015, the entire contents of which are incorporated herein by reference.

### FIELD

Embodiments described herein relate generally to a semiconductor device and, more particularly, to a semiconductor device using a compound semiconductor.

### BACKGROUND

A field plate electrode is known as a field relaxing technique for an FET (Field Effect Transistor). By forming the field plate electrode so as to cover the gate electrode, it is possible to relax field concentration near the gate electrode, and as a consequence increase the breakdown voltage of the FET.

Unfortunately, the parasitic capacitance increases when the field plate structure is adopted. This is disadvantageous for a high-speed operation of the FET.

### BRIEF DESCRIPTION OF THE DRAWINGS

FIG. 1 is a plan view of a semiconductor device according to the first embodiment;

FIG. 2 is a sectional view of the semiconductor device taken along a line A-A′ shown in FIG. 1;

FIG. 3 is a sectional view of the semiconductor device taken along a line B-B′ shown in FIG. 1;

FIG. 4 is a plan view of a semiconductor device according to the second embodiment;

FIG. 5 is a sectional view of the semiconductor device taken along a line A-A′ shown in FIG. 4;

FIG. 6 is a plan view of a semiconductor device according to the third embodiment;

FIG. 7 is a sectional view of the semiconductor device taken along a line A-A′ shown in FIG. 6;

FIG. 8 is a sectional view of the semiconductor device taken along a line B-B′ shown in FIG. 6;

FIG. 9 is a plan view of a semiconductor device according to the fourth embodiment;

FIG. 10 is a sectional view of the semiconductor device taken along a line A-A′ shown in FIG. 9; and

FIG. 11 is a sectional view of the semiconductor device taken along a line B-B′ shown in FIG. 9.

### DETAILED DESCRIPTION

In general, according to one embodiment, there is provided a semiconductor device comprising:

a field effect transistor provided in a semiconductor layer and including a gate electrode, a source electrode, and a drain electrode;

a first insulating layer provided on the field effect transistor;

a first field plate electrode provided on the first insulating layer to overlap the gate electrode, and coupled to one of the gate electrode and the source electrode;

a second insulating layer provided on the first field plate electrode; and

a second field plate electrode provided on the second insulating layer and above the first field plate electrode, and coupled to the other one of the gate electrode and the source electrode,

wherein the second field plate electrode includes a first electrode portion and a second electrode portion spaced apart by a first space.

Embodiments will be explained below with reference to the accompanying drawings. However, these drawings are schematic or conceptual, so the dimensions, ratios, and the like in the drawings are not necessarily the same as real ones. Several embodiments to be presented below exemplify a device and method for embodying the technical idea of the present invention, but the technical idea of the present invention is not specified by the shapes, structures, layouts, and the like of the constituent components. Note that in the following explanation, the same reference numerals denote elements having the same functions and arrangements, and a repetitive explanation will be made only when necessary.

### First Embodiment

A semiconductor device 1 includes an FET (Field Effect Transistor). In this embodiment, the FET is formed by an HFET (Heterojunction FET) or a HEMT (High Electron Mobility Transistor). This embodiment will be explained by taking, as an example, a HEMT (or HFET) using a nitride semiconductor as a compound semiconductor.

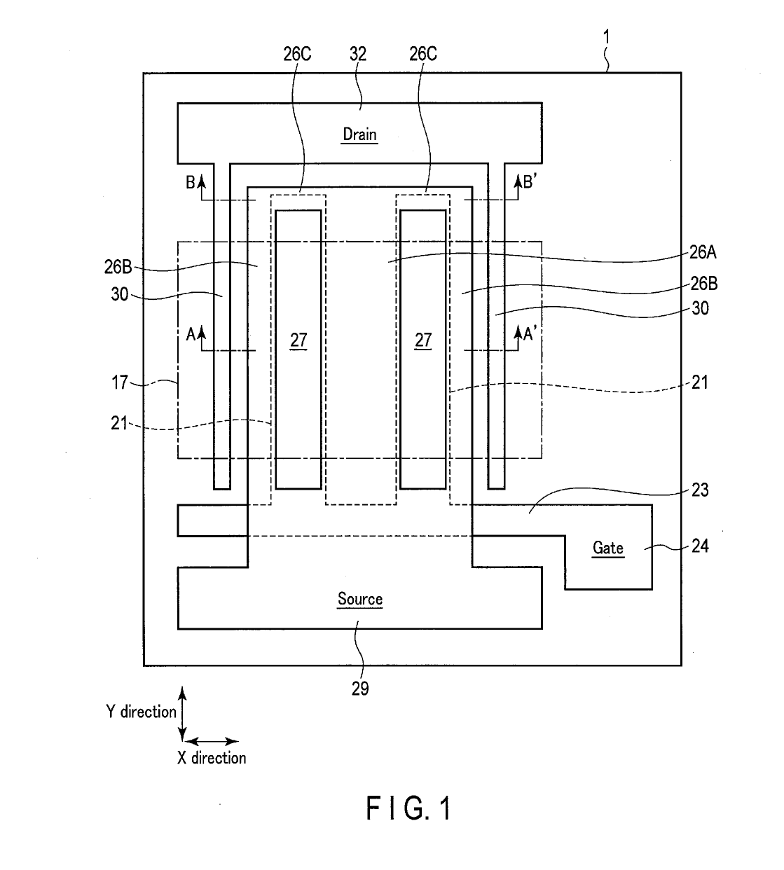

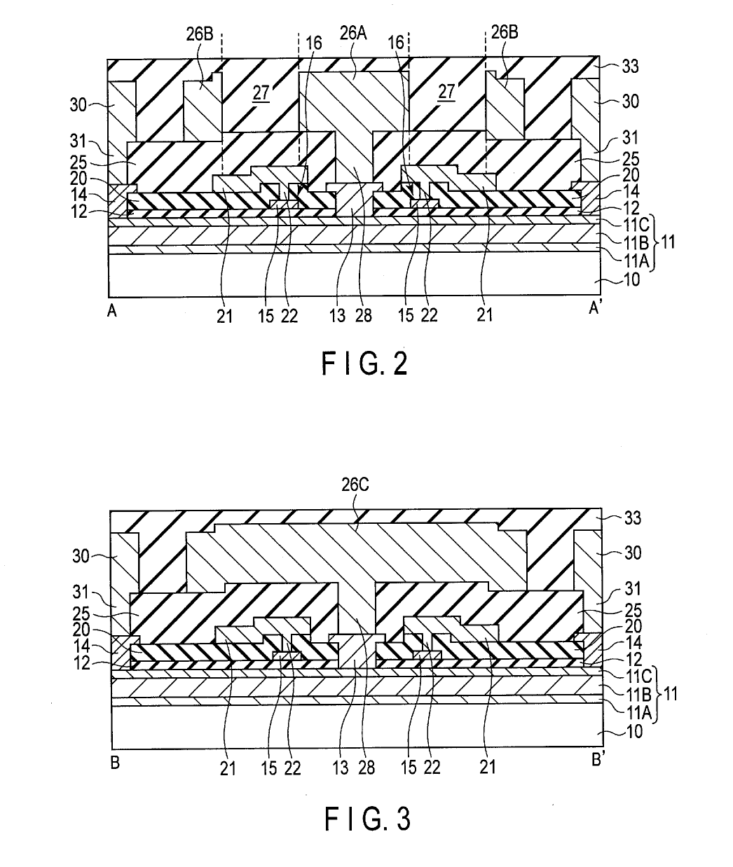

FIG. 1 is a plan view of the semiconductor device 1 according to the first embodiment. FIG. 2 is a sectional view of the semiconductor device 1 taken along a line A-A′ shown in FIG. 1. FIG. 3 is a sectional view of the semiconductor device 1 taken along a line B-B′ shown in FIG. 1. Note that FIG. 1 specifically shows one source electrode, and two HEMTs sharing the source electrode. In practice, a plurality of HEMTs are so formed as to alternately share the source electrode and drain electrode.

A substrate 10 is formed by, e.g., a silicon (Si) substrate having a (111) face as a principal surface. As the substrate 10, it is also possible to use, e.g., silicon carbide (SiC), gallium nitride (GaN), gallium phosphide (GaP), indium phosphide (InP), gallium arsenide (GaAs), or sapphire (Al₂O₃).

A nitride semiconductor layer 11 is formed by, e.g., stacking three layers, i.e., a buffer layer 11A, channel layer 11B, and barrier layer 11C. An active region (active area) 17 is formed in the nitride semiconductor layer 11, and the plurality of HEMTs of the semiconductor device 1 are formed in the active region 17. The active region 17 is a region where carriers are activated. More specifically, an impurity element (e.g., argon (Ar), nitrogen (N), or carbon (C)) is doped in a region (element isolation region) of the nitride semiconductor except for the active region, thereby destroying or deteriorating the crystal structure of the nitride semiconductor, and inactivating carriers in the element isolation region. Thus, the active region 17 and the element isolation region surrounding the active region 17 are formed in the semiconductor device 1.

A buffer layer 11A is provided on the substrate 10. The buffer layer 11A has a function of relaxing strain caused by a difference between the lattice constant of the nitride semiconductor layer formed on the buffer layer 11A and the lattice constant of the substrate 10, and a function of controlling the crystallinity of the nitride semiconductor layer formed on the buffer layer 11A. The buffer layer 11A is made of, e.g., Al_{X}Ga_{1-X}N (0≦X≦1). The buffer layer 11A may also be formed by stacking a plurality of Al_{X}Ga_{1-X}N layers having different composition ratios. When forming the buffer layer 11A by this multilayered structure, the composition ratio of the multilayered structure is adjusted such that the lattice constants of the plurality of layers included in the multilayered structure change from the lattice constant of a lower one of upper and lower layers sandwiching the buffer layer 11A toward the lattice constant of the upper layer.

A channel layer 11B is provided on the buffer layer 11A. The channel layer 11B is a layer in which the channel (current path) of the transistor is formed. The channel layer 11B is formed by Al_{X}In_{Y}Ga_{1-(X+Y)}N (0≦X<1, 0≦Y<1, 0≦X+Y<1). The channel layer 11B is, e.g., an undoped layer, and is formed by a nitride semiconductor having high crystallinity (high quality). “Undoped” means that no impurity is intentionally doped, and includes, e.g., an amount of impurity entering during the manufacturing process or the like. In this embodiment, the channel layer 11B is made of undoped GaN (also called intrinsic GaN).

A barrier layer 11C is provided on the channel layer 11B. The barrier layer 11C is formed by Al_{X}In_{Y}Ga_{1-(X+Y)}N (0≦X<1, 0≦Y<1, 0≦X+Y<1). The barrier layer 11C is made of a nitride semiconductor having a bandgap larger than that of the channel layer 11B. In this embodiment, the barrier layer 11C is made of, e.g., undoped AlGaN.

Note that the plurality of semiconductor layers forming the semiconductor device 1 are sequentially formed by, e.g., epitaxial growth using MOCVD (Metal Organic Chemical Vapor Deposition). That is, the plurality of semiconductor layers forming the semiconductor device 1 are formed by epitaxial layers.

A source electrode 13 and drain electrode 14 are provided on the barrier layer 11C so as to be spaced apart from each other. The source electrode 13 and drain electrode 14 extend in the Y direction, and cross the active region 17 in the Y direction. The source electrode 13 and barrier layer 11C are in ohmic contact with each other. Similarly, the drain electrode 14 and barrier layer 11C are in ohmic contact with each other. That is, each of the source electrode 13 and drain electrode 14 is so formed as to contain a material which comes in ohmic contact with the barrier layer 11C. As the source electrode 13 and drain electrode 14, it is possible to use, e.g., an Al/Ti multilayered structure. The left side of “/” indicates an upper layer, and the right side of “/” indicates a lower layer.

A gate insulating film 12 is formed between the source electrode 13 and drain electrode 14 on the barrier layer 11C. A gate electrode 15 is provided on the gate insulating film 12. For example, to increase the gate-drain breakdown voltage, the distance between the gate electrode 15 and drain electrode 14 is set longer than that between the gate electrode 15 and source electrode 13. The gate electrode 15 extends in the Y direction and crosses the active region 17 in the Y direction. As the gate insulating film 12, it is possible to use, e.g., silicon oxide (SiO₂), silicon nitride (SiN), or aluminum nitride (AlN). As the gate electrode 15, it is possible to use, e.g., nickel (Ni) or titanium (Ti).

The HEMT 16 is formed by the source electrode 13, the drain electrode 14, the gate electrode 15, the gate insulating film 12, and a portion of the nitride semiconductor layer 11. The HEMT of this embodiment is a MIS (Metal Insulator Semiconductor) HEMT. Note that the HEMT 16 is not limited to the MIS HEMT, and may also be a Schottky barrier HEMT formed by connecting the gate electrode 15 and barrier layer 11C by a Schottky junction without using the gate insulating film 12. It is also possible to apply a junction gate structure to the HEMT. The junction gate structure is obtained by forming a p-type nitride semiconductor layer (e.g., a GaN layer) on the barrier layer 11C, and forming the gate electrode 15 on this p-type nitride semiconductor layer.

In the heterojunction structure of the channel layer 11B and barrier layer 11C, strain occurs in the barrier layer 11C because the lattice constant of the barrier layer 11C is smaller than that of the channel layer 11B. Piezoelectric polarization occurs in the barrier layer 11C due to the piezoelectric effect caused by this strain, and a two-dimensional electron gas (2DEG) is produced near the interface of the channel layer 11B with respect to the barrier layer 11C. This two-dimensional electron gas functions as a channel between the source electrode 13 and drain electrode 14. In accordance with a gate voltage to be applied to the gate electrode 15, and an electric field to be applied to the channel layer 11B, this makes it possible to control a drain current.

### (Arrangement of Field Plate Electrode)

The semiconductor device 1 includes a field plate electrode (gate field plate electrode) electrically connected to the gate electrode 15, and a field plate electrode (source field plate electrode) electrically connected to the source electrode 13. That is, the semiconductor device 1 has a so-called double field plate structure.

Details of the field plate electrode will be explained below. Note that the field plate electrode connected to one HEMT 16 will be explained below, but this explanation applies to a plurality of other HEMTs.

An interlayer dielectric layer 20 is provided on the gate electrode 15 and gate insulating film 12. As the interlayer dielectric layer 20, it is possible to use, e.g., silicon oxide (SiO₂), silicon nitride (SiN), or a high dielectric constant film (high-k film). An example of the high-k film is hafnium oxide (HfO₂).

A gate field plate electrode 21 is provided on the interlayer dielectric layer 20. The gate field plate electrode 21 is electrically connected to the gate electrode 15 via a contact 22. The contact 22 need only have a function of electrically connecting the gate field plate electrode 21 and gate electrode 15, so the arrangement and layout of the contact 22 can freely be designed. The contact 22 can be laid out on only the outside of the active region 17, on only the inside of the active region 17, or on both the outside and inside of the active region 17. Furthermore, it is possible to form a plurality of columnar contacts 22 or a linear contact 22.

The gate field plate electrode 21 extends in the Y direction and crosses the active region 17 in the Y direction. Also, the gate field plate electrode 21 extends toward the drain electrode 14 while covering the two ends (edges) of the gate electrode 15 in the X direction (a direction perpendicular to the Y direction). The width of the gate field plate electrode 21 in the X direction is set larger than that of the gate electrode 15 in the X direction. The gate field plate electrode 21 is electrically connected to an electrode 23 extending in the X direction. The electrode 23 is electrically connected to a gate electrode pad 24.

An interlayer dielectric layer 25 is provided on the gate field plate electrode 21 and interlayer dielectric layer 20. As the interlayer dielectric layer 25, it is possible to use, e.g., silicon oxide (SiO₂), silicon nitride (SiN), or a high-k film.

A source field plate electrode 26 (26A, 26B, and 26C) is provided on the interlayer dielectric layer 25. The source field plate electrode 26 is electrically connected to the source electrode 13 via a contact 28. The source field plate electrode 26 is also electrically connected to a source electrode pad 29.

In the active region 17, the source field plate electrode 26 is divided into electrodes 26A and 26B. The electrodes 26A and 26B extend in the Y direction and cross the active region 17 in the Y direction. In this embodiment, the electrodes 26A and 26B are electrically connected by an electrode 26C at the end portion in the Y direction. The electrodes 26A and 26B are spaced apart by an opening (space) 27. Note that the source field plate electrode 26 may also be formed into a comb shape without forming the electrode 26C. That is, the comb-shaped source field plate electrode 26 is so formed as to include the electrodes 26A and 26B extending in the Y direction from the electrode pad 29.

The end portion of the source field plate electrode 26 is placed closer to the drain electrode 14 than the end portion of the gate field plate electrode 21 in the X direction. The opening 27 of the source field plate electrode 26 is formed above the gate field plate electrode 21.

In this embodiment, the overlap region of the source field plate electrode 26 and gate field plate electrode 21 is reduced in a planar view. That is, in the active region 17, the source field plate electrode 26 is so formed as to overlap only the end portions of the gate field plate electrode 21. The end of the electrode 26A is placed closer to the drain electrode 14 than the end (on the source electrode 13 side) of the gate field plate electrode 21. The end (on the source electrode 13 side) of the electrode 26B is placed closer to the source electrode 13 than the end (on the drain electrode 14 side) of the gate field plate electrode 21. The electrode 26B extends from the end portion of the gate field plate electrode 21 toward the drain electrode 14.

An electrode 30 is provided on a contact 31 on the drain electrode 14. The electrode 30 extends in the Y direction and crosses the active region 17 in the Y direction. The electrode 30 is electrically connected to a drain electrode pad 32.

A protective layer 33 is provided on the interlayer dielectric layer 20, source field plate electrode 26, and electrode 30. The protective layer 33 is also called a passivation layer. The protective layer 33 is made of an insulator, and silicon nitride (SiN), silicon oxide (SiO₂), or the like is used.

### (Effects)

In the first embodiment as has been explained in detail above, the semiconductor device 1 includes the gate field plate electrode 21 electrically connected to the gate electrode 15, and the source field plate electrode 26 electrically connected to the source electrode 13 and arranged above the gate field plate electrode 21. The source field plate electrode 26 includes the electrodes 26A and 26B spaced apart by the opening (space) 27. The opening 27 is formed above the gate field plate electrode 21.

Accordingly, the first embodiment can reduce the area of the overlap region of the gate field plate electrode 21 and source field plate electrode 26. This makes it possible to reduce a parasitic capacitance caused by the field plate electrode. Therefore, a high-speed operation of the semiconductor device 1 is possible.

An electric field tends to concentrate to the vicinity of the gate electrode and to the upper surface of the semiconductor nitride layer. In particular, an electric field tends to concentrate to the end portion of the gate electrode on the drain electrode side. In this embodiment, however, the gate electrode 15 is covered with the gate field plate electrode 21. Since this reduces field concentration near the gate electrode 15, the breakdown voltage of the semiconductor device 1 can be increased.

Also, the end portions of the electrodes 26A and 26B included in the source field plate electrode 26 are arranged above the end portions of the gate field plate electrode 21. This makes it possible to reduce the number of field concentration points corresponding to the end of the field plate electrode. Accordingly, the breakdown voltage of the semiconductor device 1 can be increased.

### Second Embodiment

In the second embodiment, a source field plate electrode 26 is divided into two electrodes in an active region 17, so that the source field plate electrode and a gate field plate electrode 21 do not overlap each other.

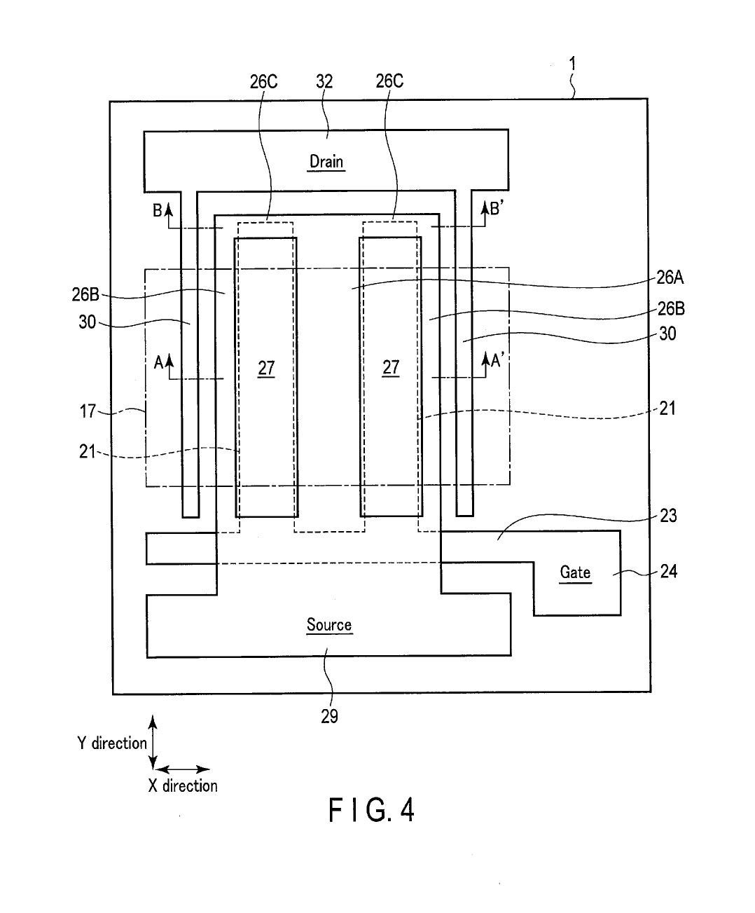

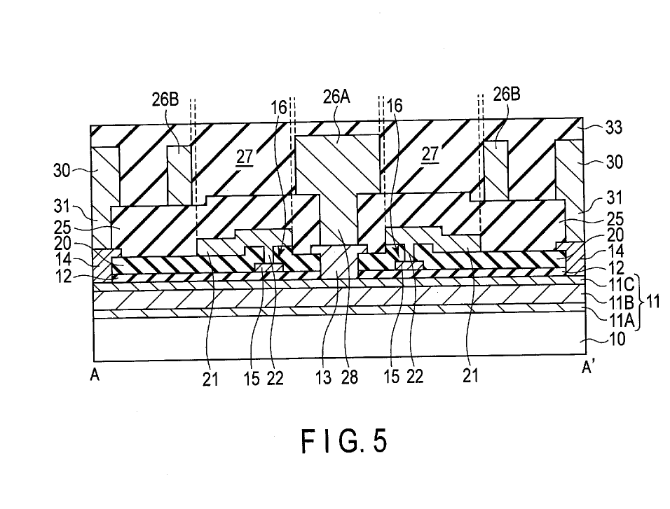

FIG. 4 is a plan view of a semiconductor device 1 according to the second embodiment. FIG. 5 is a sectional view of the semiconductor device 1 taken along a line A-A′ shown in FIG. 4. A sectional view of the semiconductor device 1 taken along a line B-B′ shown in FIG. 4 is the same as FIG. 3.

In the active region 17, the source field plate electrode 26 is so formed as not to overlap the gate field plate electrode 21. More specifically, the end of an electrode 26A is placed closer to a source electrode 13 than the end (on the source electrode 13 side) of the gate field plate electrode 21. The end (on the source electrode 13 side) of an electrode 26B is placed closer to a drain electrode 14 than the end (on the drain electrode 14 side) of the gate field plate electrode 21. The rest of the arrangement is the same as that of the first embodiment.

The second embodiment can reduce a parasitic capacitance caused by the field plate electrode more than that in the first embodiment. Also, since the number of field concentration points caused by the field plate electrode increases, the peak electric field of each field concentration point can be reduced. This makes it possible to increase the breakdown voltage of the semiconductor device 1. Other effects are the same as those of the first embodiment.

### Third Embodiment

In the third embodiment, a source field plate electrode is formed into a planar shape, and a gate field plate electrode is divided.

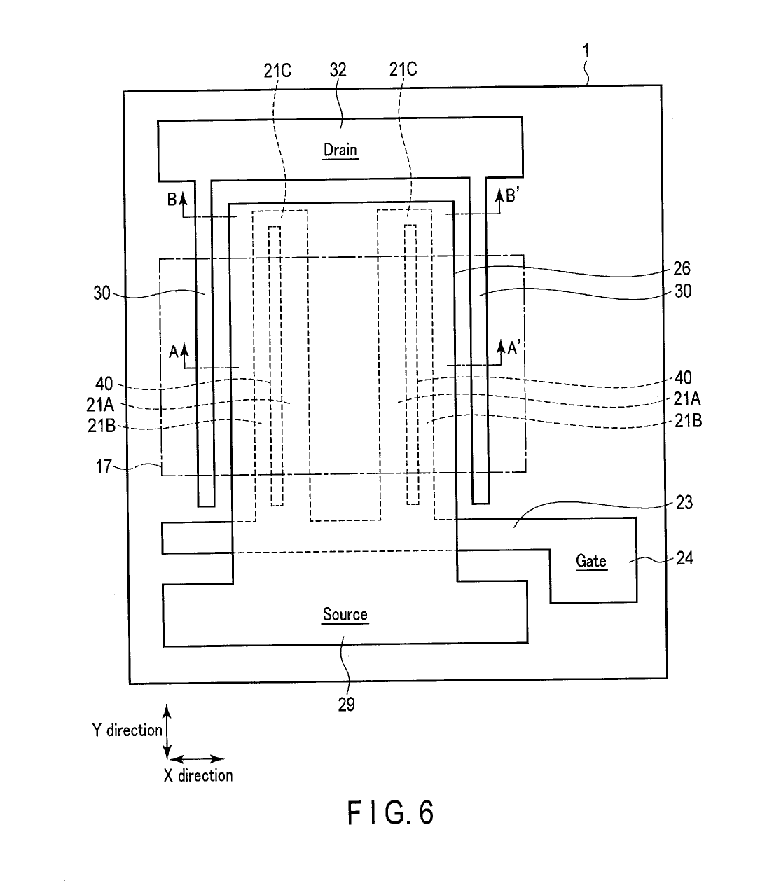

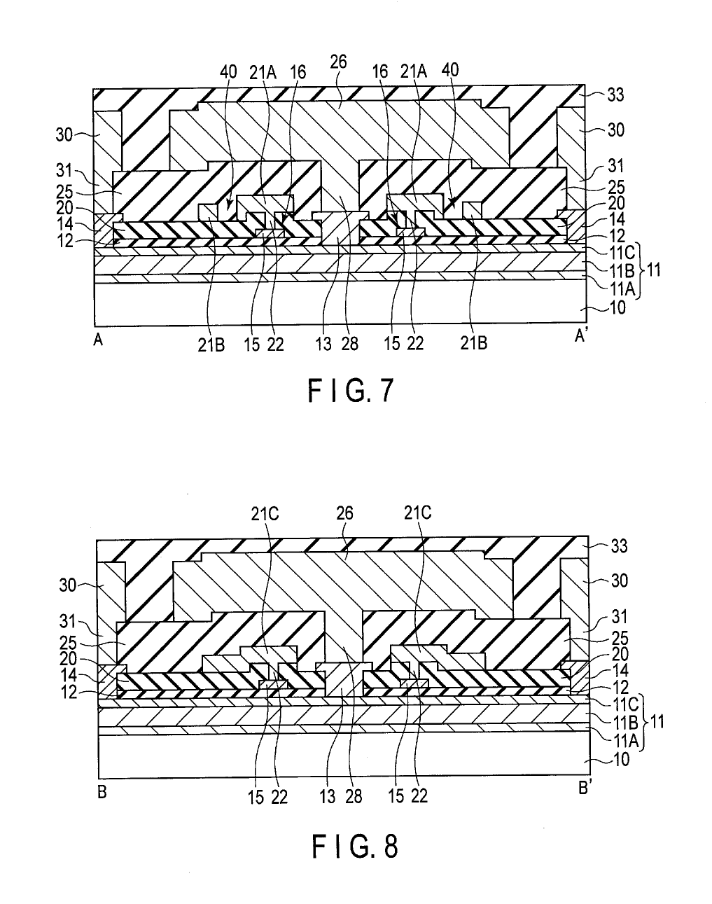

FIG. 6 is a plan view of a semiconductor device 1 according to the third embodiment. FIG. 7 is a sectional view of the semiconductor device 1 taken along a line A-A′ shown in FIG. 6. FIG. 8 is a sectional view of the semiconductor device 1 taken along a line B-B′ shown in FIG. 6.

In an active region 17, a gate field plate electrode 21 is divided into electrodes 21A and 21B. The electrodes 21A and 21B extend in the Y direction and cross the active region 17 in the Y direction. In this embodiment, the electrodes 21A and 21B are electrically connected by an electrode 21C in the end portion in the Y direction. The electrodes 21A and 21B are spaced apart by an opening (space) 40. Note that the gate field plate electrode 21 may also be formed into a comb shape without forming the electrode 21C. That is, the comb-shaped gate field plate electrode 21 is so formed as to include the electrodes 21A and 21B extending in the Y direction from an electrode 23.

A source field plate electrode 26 is not divided into a plurality of electrodes, but formed into a planar shape. The source field plate electrode 26 is so formed as to cover the gate field plate electrode 21. That is, the end of the source field plate electrode 26 is placed closer to a drain electrode 14 than the end (on the drain electrode 14 side) of the gate field plate electrode 21.

In the third embodiment as has been described in detail above, the gate field plate electrode 21 is divided into a plurality of electrodes. This makes it possible to reduce the area of an overlap region of the gate field plate electrode 21 and source field plate electrode 26. Accordingly, a parasitic capacitance caused by the field plate electrode can be reduced.

The space between the electrodes 21A and 21B forming the field plate electrode 21 can appropriately be set. To reduce the capacitance, however, the space between the electrodes 21A and 21B is desirably as large as possible. By increasing the space between the electrodes 21A and 21B, the area of the overlap region of the gate field plate electrode 21 and source field plate electrode 26 can be reduced.

### Fourth Embodiment

The fourth embodiment further reduces a parasitic capacitance by dividing both a gate field plate electrode and source field plate electrode.

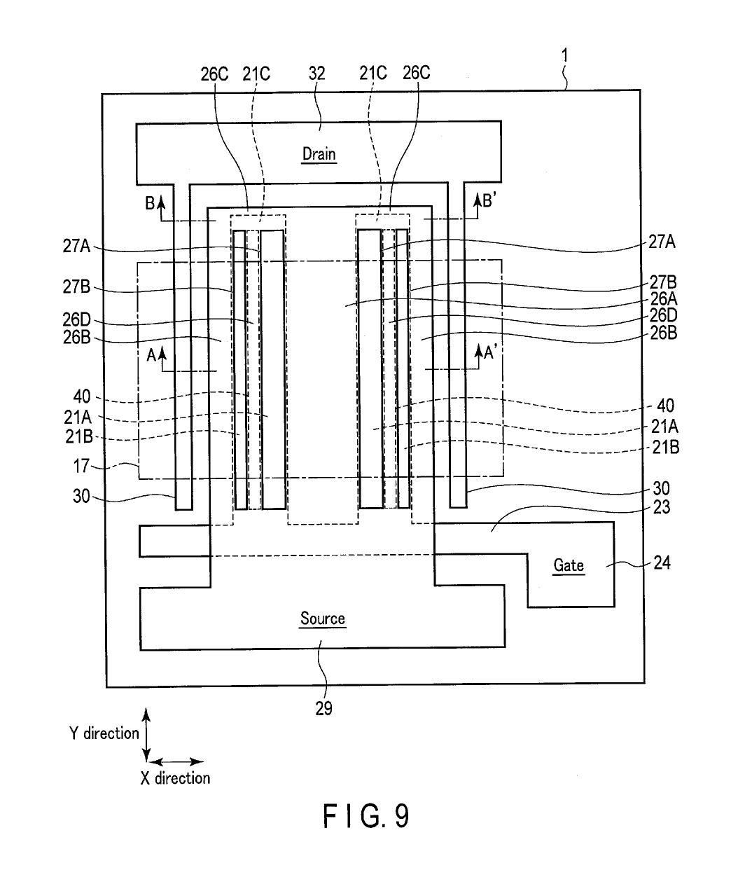

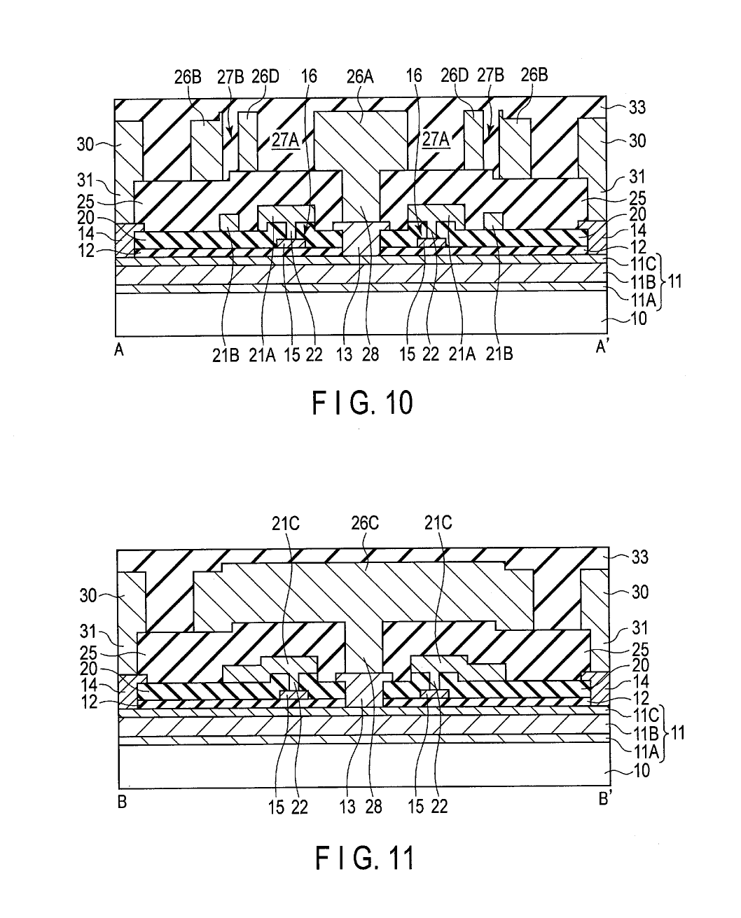

FIG. 9 is a plan view of a semiconductor device 1 according to the fourth embodiment. FIG. 10 is a sectional view of the semiconductor device 1 taken along a line A-A′ shown in FIG. 9. FIG. 11 is a sectional view of the semiconductor device 1 taken along a line B-B′ shown in FIG. 9.

The arrangement of a gate field plate electrode 21 is the same as that in the third embodiment. That is, the gate field plate electrode 21 is divided into electrodes 21A and 21B in an active region 17.

In the active region 17, a source field plate electrode 26 is so formed as to overlap only the end portions of the gate field plate electrode 21. More specifically, the source field plate electrode 26 is divided into electrodes 26A, 26B, and 26D. The electrodes 26A, 26B, and 26D extend in the Y direction and cross the active region 17 in the Y direction. In this embodiment, the electrodes 26A, 26B, and 26D are electrically connected by an electrode 26C in the end portion in the Y direction.

The electrodes 26A and 26D are spaced apart by an opening 27A, and the electrodes 26D and 26B are spaced apart by an opening 27B. The opening 27A is formed above the gate electrode 21A. The opening 27B is formed above the gate electrode 21B.

As in the first embodiment, the source electrode 26A and gate electrode 21A are so arranged that the end portions overlap each other. The two end portions of the source electrode 26D are so arranged as to overlap the end portions of the gate electrodes 21A and 21B. The end portion of the source electrode 26B is so placed as to overlap the end portion of the gate electrode 21B.

Note that as in the second embodiment, the source field plate electrode 26 may also be so formed as not to overlap the gate field plate electrode 21 in the active region 17.

Note also that the source field plate electrode 26 may also be formed into a comb shape without forming the electrode 26C. That is, the comb-shaped source field plate electrode 26 is so formed as to include the electrodes 26A, 26B, and 26D extending in the Y direction from an electrode pad 29.

As has been described in detail above, the fourth embodiment can further reduce the area of an overlap region of the gate field plate electrode 21 and source field plate electrode 26. This makes it possible to further reduce a parasitic capacitance caused by the field plate electrode.

Note that the number of electrodes obtained by dividing the source field plate electrode is not limited to that of the above-mentioned embodiments, and may also be larger than that. Likewise, the gate field plate electrode may also be divided into a larger number of electrodes.

Note also that in the above-mentioned embodiments, the gate field plate electrode is positioned on the lower side, and the source field plate electrode is positioned on the upper side. However, the present invention is not limited to this, and the positions of the gate field plate electrode and source field plate electrode may also be switched (i.e., the gate field plate electrode on the upper side, and the source field plate electrode on the lower side).

In each embodiment, the semiconductor device is formed by using a nitride semiconductor. However, the present invention is not limited to this, and is also applicable to a compound semiconductor other than a nitride semiconductor.

In this specification, “a nitride semiconductor” includes semiconductors having all compositions in which composition ratios x and y are changed in their respective ranges in a chemical formula represented by InₓAl_{y}Ga_{(1-x-y)}N (0≦x≦1, 0≦y≦1, 0≦x+y≦1). In this chemical formula, “a nitride semiconductor” also includes a semiconductor further containing a group-V element other than N (nitrogen), a semiconductor further containing various elements added to control various physical properties such as a conductivity type, and a semiconductor further containing various unintentionally contained elements.

In this specification, “stack” includes not only a case in which layers are overlaid in contact with each other, but also a case in which layers are overlaid with another layer being inserted between them. Also, “provided on” includes not only a case in which a layer is provided on another layer in contact with each other, but also a case in which a layer is provided on another layer with still another layer being inserted between them.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a field effect transistor provided in a semiconductor layer and including a gate electrode, a source electrode, and a drain electrode;
a first insulating layer provided on the field effect transistor;
a first field plate electrode provided on the first insulating layer to overlap the gate electrode, and coupled to one of the gate electrode and the source electrode;
a second insulating layer provided on the first field plate electrode; and
a second field plate electrode provided on the second insulating layer and above the first field plate electrode, and coupled to the other one of the gate electrode and the source electrode,
wherein the second field plate electrode includes a first electrode portion and a second electrode portion spaced apart by a first space.

2. The device of claim 1, wherein
the first field plate electrode is coupled to the gate electrode, and
the second field plate electrode is coupled to the source electrode.

3. The device of claim 1, wherein the first space is provided above the first field plate electrode.

4. The device of claim 1, wherein a width of the second field plate electrode is larger than that of the first field plate electrode.

5. The device of claim 1, wherein the first electrode portion and the second electrode portion partially overlap the first field plate electrode.

6. The device of claim 1, wherein the first electrode portion and the second electrode portion do not overlap the first field plate electrode.

7. The device of claim 1, wherein the second field plate electrode includes a third electrode portion which couples the first electrode portion and the second electrode portion.

8. The device of claim 1, wherein the first field plate electrode includes a fourth electrode portion and a fifth electrode portion spaced apart by a second space.

9. The device of claim 1, wherein the second space partially overlaps the second field plate electrode.

10. The device of claim 1, wherein the first field plate electrode includes a sixth electrode portion which couples the fourth electrode portion and the fifth electrode portion.

11. The device of claim 1, wherein
the first field plate electrode covers an edge of the gate electrode, and
the second field plate electrode covers an edge of first field plate electrode.

12. The device of claim 1, wherein the semiconductor layer includes a nitride semiconductor layer.

13. The device of claim 1, wherein the field effect transistor is a heterojunction field effect transistor (HFET).

14. A semiconductor device comprising:
a field effect transistor provided in a semiconductor layer and including a gate electrode, a source electrode, and a drain electrode;
a first insulating layer provided on the field effect transistor;
a first field plate electrode provided on the first insulating layer to overlap the gate electrode, and coupled to one of the gate electrode and the source electrode;
a second insulating layer provided on the first field plate electrode; and
a second field plate electrode provided on the second insulating layer to overlap the field plate electrode, and coupled to the other one of the gate electrode and the source electrode,
wherein the first field plate electrode includes a first electrode portion and a second electrode portion spaced apart by a space.

15. The device of claim 14, wherein
the first field plate electrode is coupled to the gate electrode, and
the second field plate electrode is coupled to the source electrode.

16. The device of claim 14, wherein the space is provided below the second field plate electrode.

17. The device of claim 14, wherein a width of the second field plate electrode is larger than that of the first field plate electrode.

18. The device of claim 14, wherein the first field plate electrode includes a third electrode portion which couples the first electrode portion and the second electrode portion.

19. The device of claim 14, wherein
the first field plate electrode covers an edge of the gate electrode, and
the second field plate electrode covers an edge of first field plate electrode.

20. The device of claim 14, wherein the semiconductor layer includes a nitride semiconductor layer.
